(19) United States
(12) Patent Application Publication
(10) Pub. No.: US 2026/0220342 A1
(43) Pub. Date: Jul. 30, 2026

(54) METHOD OF TESTING SEMICONDUCTOR PRODUCT USING PROBABILITY MODEL-BASED TEST, TEST EQUIPMENT PERFORMING THE SAME AND METHOD OF MANUFACTURING SEMICONDUCTOR PRODUCT USING THE SAME

(71) Applicant: Samsung Electronics Co., Ltd., Suwon-si (KR)

(72) Inventors: Minkyu Yang, Suwon-si (KR); Young Lee, Suwon-si (KR); Jinsic Jang, Suwon-si (KR); Jongrok Choi, Suwon-si (KR)

(21) Appl. No.: 19/452,568

(22) Filed: Jan. 19, 2026

(30) Foreign Application Priority Data
Jan. 24, 2025 (KR) 10-2025-0011262

(51) Int. Cl. G06F 30/333

(52) U.S. Cl. CPC G06F 30/333

(57) ABSTRACT

In a test method, a first test operation is performed on semiconductor products mounted on a test board to determine whether each semiconductor product is normal or defective. The test board includes a plurality of test channels, and two or more semiconductor products share a single test channel. A test map representing a result of the first test operation is generated. The test map is divided into a first region and a second region, and the first region identifies semiconductor products that share the same test channel and have been determined to be entirely defective. The second region identifies semiconductor products other than those identified in the first region. A second test operation is performed to determine whether defects of semiconductor products included in the first region are board-related defects caused by a characteristic of the test board, using information of the first and second regions, a first probability model, and a second probability model.

### CROSS-REFERENCE TO RELATED APPLICATION

This application claims priority under 35 USC § 119 to Korean Patent Application No. 10-2025-0011262 filed on Jan. 24, 2025, in the Korean Intellectual Property Office (KIPO), the content of which is herein incorporated by reference in its entirety.

### BACKGROUND

### 1. Technical Field

Example embodiments relate generally to semiconductor integrated circuits, and more particularly to methods of testing semiconductor products using probability model-based test, test equipment performing the methods of testing the semiconductor products, and methods of manufacturing semiconductor products using the methods of testing the semiconductor products.

### 2. Description of the Related Art

Semiconductor products may be manufactured through several processes, such as oxidation processes, photolithography processes, etching processes, deposition processes, ion implantation processes, metal wiring processes, etc. on semiconductor wafers. Currently, most semiconductor products may be tested using automatic test equipment (ATE) for enhancing productivity of manufacturing the semiconductor products.

As a result of the test using the automatic test equipment, some of the semiconductor products may be determined as defective either due to a defect of the semiconductor products themselves, or due to errors of the test equipment. Because the semiconductor products determined to be defective due to the errors of the test equipment should be recovered through a retest, additional time, cost, and effort for distinguishing defects caused by the errors of the test equipment from defects of the semiconductor products themselves are often required.

### SUMMARY

At least one example embodiment of the present disclosure provides a method of testing a semiconductor product capable of efficiently detecting and treating a defect caused by an error on test equipment using a probability model-based test.

At least one example embodiment of the present disclosure provides test equipment performing the method of testing the semiconductor product.

At least one example embodiment of the present disclosure provides a method of manufacturing a semiconductor product using the method of testing the semiconductor product.

According to example embodiments, a method of testing a semiconductor product includes performing a first test operation on a plurality of semiconductor products mounted on a test board to determine whether each of the plurality of semiconductor products is normal or defective, the test board including a plurality of test channels configured to receive test signals, and two or more semiconductor products sharing a single test channel among the plurality of test channels, generating a test map based on a first result of the first test operation, dividing the test map into a first region and a second region based on channel layout data for the test board, the first region identifying semiconductor products, among the plurality of the semiconductor products, that share the same test channel and have been determined to be entirely defective, and the second region identifying semiconductor products other than those identified in the first region, and performing a second test operation to determine whether defects of semiconductor products identified in the first region are board-related defects caused by a characteristic of the test board, using information of the first and second regions, a first probability model, and a second probability model.

According to example embodiments, a test equipment includes a test board including a plurality of test channels for testing a plurality of semiconductor products mounted on the test board, each of the plurality of test channels configured to receive test signals, and two or more semiconductor products sharing one test channel among the plurality of test channels, a first test module configured to perform a first test operation to determine whether each of the plurality of semiconductor products is normal or defective, and to generate a test map representing a result of the first test operation, and a second test module configured to divide the test map into a first region and a second region based on channel layout data for the test board, and to perform a second test operation to determine whether defects of semiconductor products included in the first region are board-related defects caused by a characteristic of the test board, using information of the first and second regions, a first probability model, and a second probability model, the first region identifying semiconductor products that share the same test channel and have been determined to be entirely defective, the second region identifying semiconductor products other than those identified in the first region.

According to example embodiments, a method of manufacturing a semiconductor product includes fabricating a plurality of semiconductor products, and testing, using a test equipment, the plurality of semiconductor products mounted on a test board including a plurality of test channels for receiving test signals, wherein two or more semiconductor products share one test channel among the plurality of test channels, wherein testing the plurality of semiconductor products includes performing a first test operation to determine whether each of the plurality of semiconductor products mounted on the test board is normal or defective, generating a test map representing a result of the first test operation, dividing the test map into a first region and a second region based on channel layout data for the test board, the first region identifying semiconductor products that share the same test channel and have been determined to be entirely defective, the second region identifying semiconductor products other than those identified in the first region, and performing a second test operation to determine whether defects of semiconductor products identified in the first region are board-related defects caused by a characteristic of the test board, using information of the first and second regions, a first probability model and a second probability model.

In the method of testing the semiconductor product, the test equipment and the method of manufacturing the semiconductor product according to example embodiments, the test map may be obtained by performing the first test operation on each of the plurality of semiconductor products using the test board having the channel-shared structure, the test map may be divided into the first region and the second region using the channel layout data for the test board, and the second test operation may be performed to determine whether each defective semiconductor product determined as defective by the first test operation has the board-related defect using the divided regions and the predefined probability models. Accordingly, compared with a conventional method that utilizes GPUs or servers, the board-related defects may be detected and addressed with relatively less time and at a lower cost. In addition, the test equipment may be fully automated and may detect and treat the board-related defects by itself without additional GPUs or servers.

### BRIEF DESCRIPTION OF THE DRAWINGS

Illustrative, non-limiting example embodiments will be more clearly understood from the following detailed description taken in conjunction with the accompanying drawings.

FIG. 1 is a flowchart illustrating a method of testing a semiconductor product according to example embodiments.

FIG. 2 is a block diagram illustrating a test equipment according to example embodiments.

FIGS. 3A, 3B, 3C and 3D are diagrams for describing a test board included in a test equipment of FIG. 2.

FIGS. 4A and 4B are block diagrams illustrating examples of a first test module and a second test module included in a test equipment of FIG. 2.

FIG. 5 is a block diagram illustrating a test equipment according to example embodiments.

FIG. 6 is a flowchart illustrating an example of performing a second test operation in FIG. 1.

FIG. 7 is a flowchart illustrating an example of outputting a result value of a second test operation in FIG. 6.

FIGS. 8A, 8B, 8C, 8D, 9A, 9B, 9C and 9D are diagrams for describing a method of testing a semiconductor product according to example embodiments.

FIG. 10 is a flowchart illustrating a method of testing a semiconductor product according to example embodiments.

FIGS. 11A, 11B and 11C are block diagrams illustrating examples of a second test module included in a test equipment of FIG. 2.

FIG. 12 is a flowchart illustrating a method of testing a semiconductor product according to example embodiments.

FIG. 13 is a block diagram illustrating a test equipment according to example embodiments.

FIGS. 14A and 14B are block diagrams illustrating examples of a semiconductor product according to example embodiments.

FIGS. 15A and 15B are diagrams illustrating examples of a semiconductor product according to example embodiments.

FIG. 16 is a flowchart illustrating a method of manufacturing a semiconductor product according to example embodiments.

### DETAILED DESCRIPTION OF THE EMBODIMENTS

Various example embodiments will be described more fully with reference to the accompanying drawings, in which embodiments are shown. The present invention may, however, be embodied in many different forms and should not be construed as limited to the embodiments set forth herein. Like reference numerals refer to like elements throughout this application.

It will be understood that, although the terms first, second, third etc. may be used herein to describe various elements or components, these elements or components should not be limited by these terms. Unless the context indicates otherwise, these terms are only used to distinguish one element or component from another element or component. Thus, a first element or component discussed below in one section of the specification could be termed as a second element or component in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

It will be understood that when an element is referred to as being “connected to” or “connected on” another element, it can be directly connected to or on the other element or intervening elements may be present.

Items described in the singular herein may be provided in plural. Thus, the description of a single item that is provided in plural should be understood to be applicable to the remaining plurality of items unless context indicates otherwise.

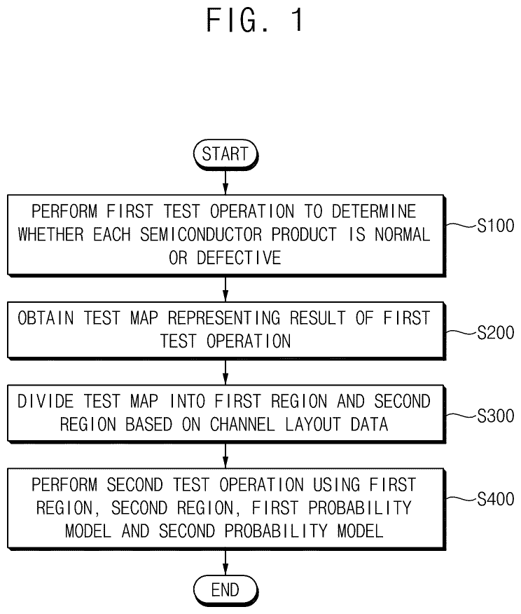

FIG. 1 is a flowchart illustrating a method of testing a semiconductor product according to example embodiments.

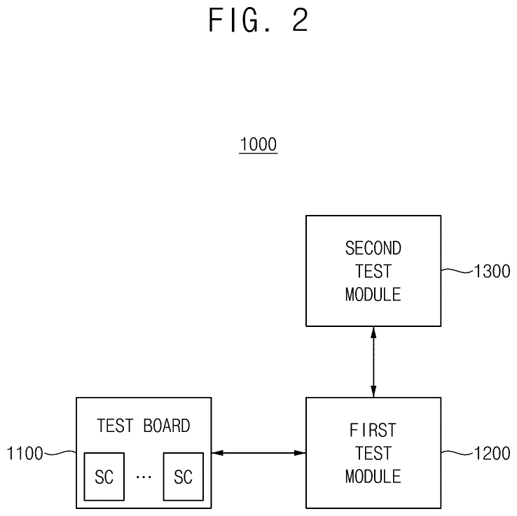

Referring to FIG. 1, a method of testing a semiconductor product according to example embodiments may be performed on a computer-based test equipment, at least part of which is implemented in hardware and/or software. For example, the test equipment may include a program (or program codes) that includes a plurality of instructions executed by at least one processor. An example configuration of the test equipment will be described with reference to FIGS. 2, 4A, 4B and 5.

In the method of testing the semiconductor product according to example embodiments, a first test operation is performed to determine whether each of a plurality of semiconductor products is normal or defective (operation S100).

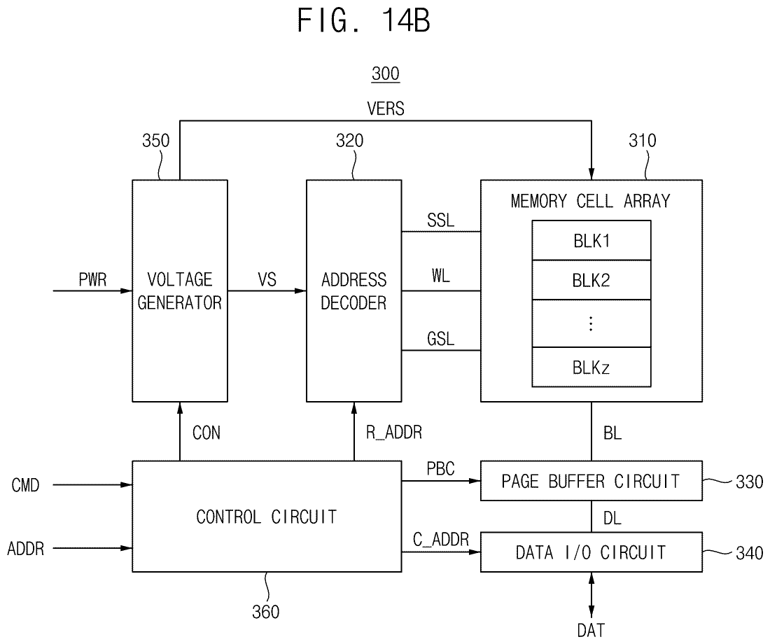

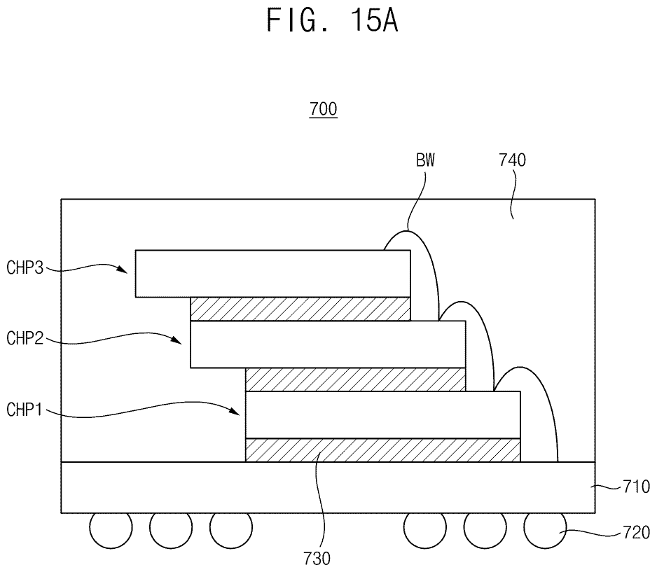

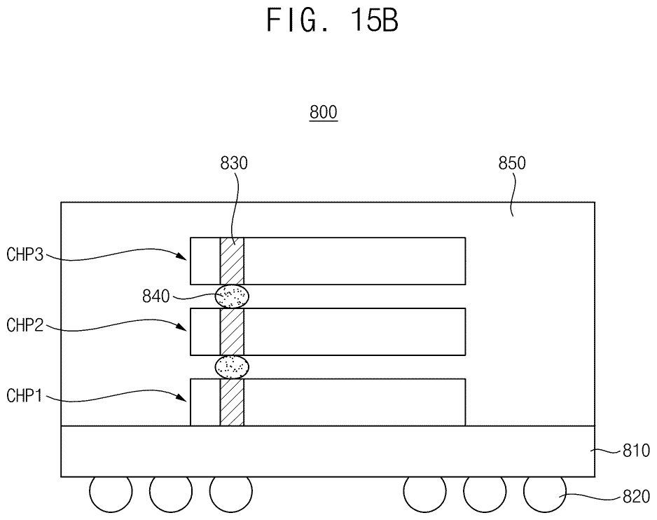

The semiconductor product to be tested may be a device under test (DUT). For example, the semiconductor product may be provided in the form of a semiconductor chip, and the semiconductor chip may be a memory chip having a data storage function. For example, the semiconductor product may be provided in the form of a semiconductor package including a plurality of semiconductor chips. Example configurations of the semiconductor product will be described with reference to FIGS. 14A, 14B, 15A and 15B.

The first test operation may be performed to determine whether each semiconductor product under the test is a normal semiconductor product that operates normally or a defective semiconductor product that operates abnormally due to its defect. The first test operation may be performed using a commonly used test method. The first test operation is performed using a test board on which the plurality of semiconductor products are mounted or equipped.

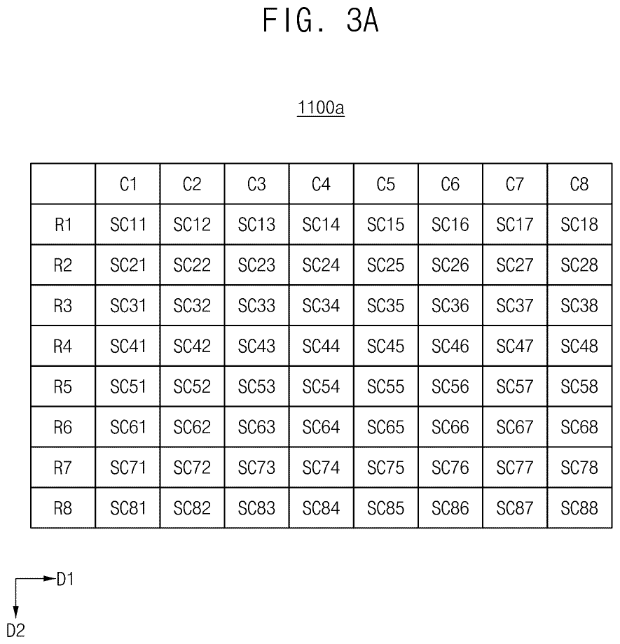

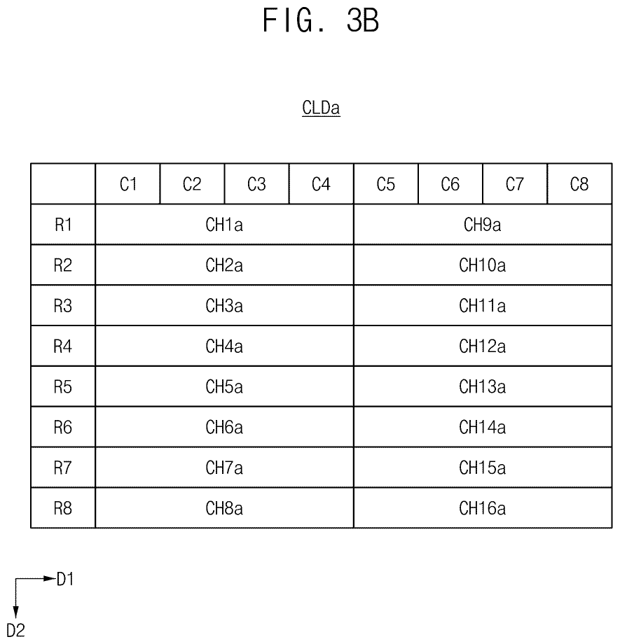

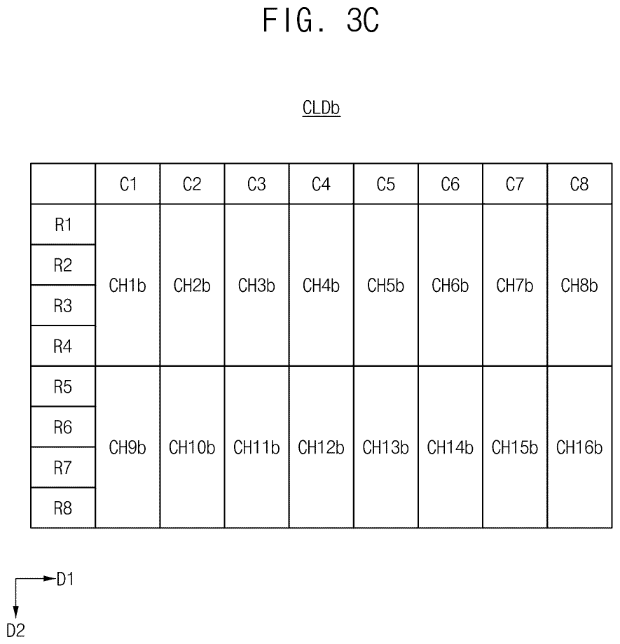

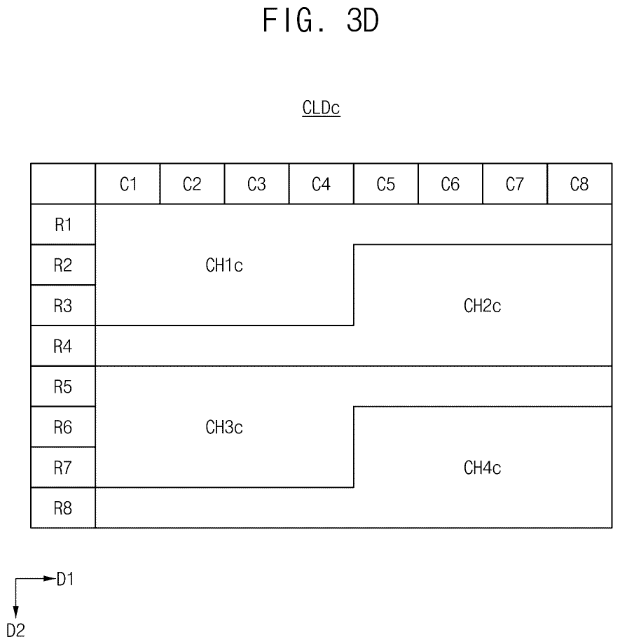

The test board includes a plurality of test channels for receiving test signals for testing the plurality of semiconductor products. For example, each semiconductor product may communicate with the test equipment through a specific test channel to which the semiconductor product is associated. For example, two or more semiconductor products among the plurality of semiconductor products mounted on the test board may share one test channel among the plurality of test channels. Such structure may be referred to as a channel-shared structure, and the test board having the channel-shared structure may be referred to as a channel-shared board. Example configurations of the test board and the plurality of test channels will be described with reference to FIGS. 3A, 3B, 3C and 3D.

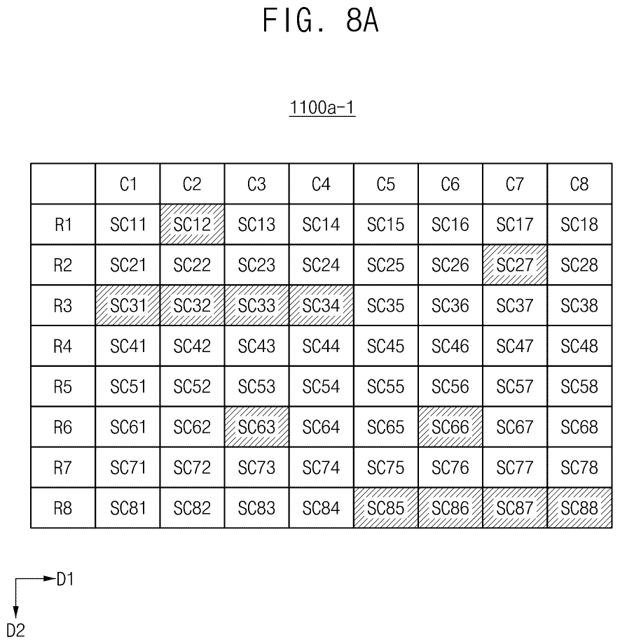

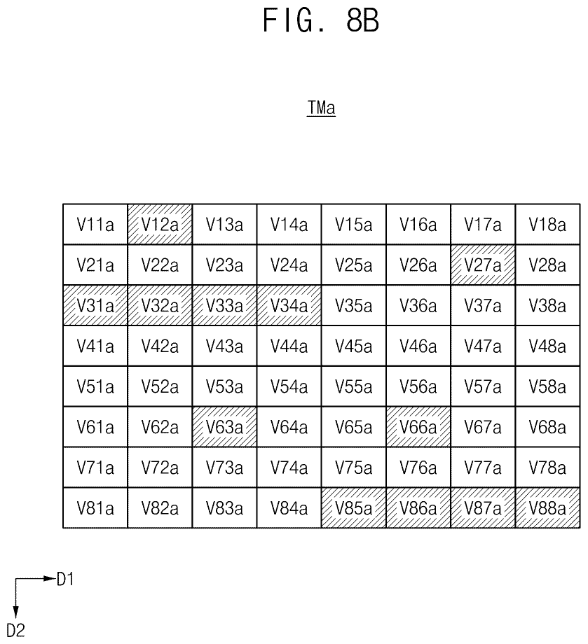

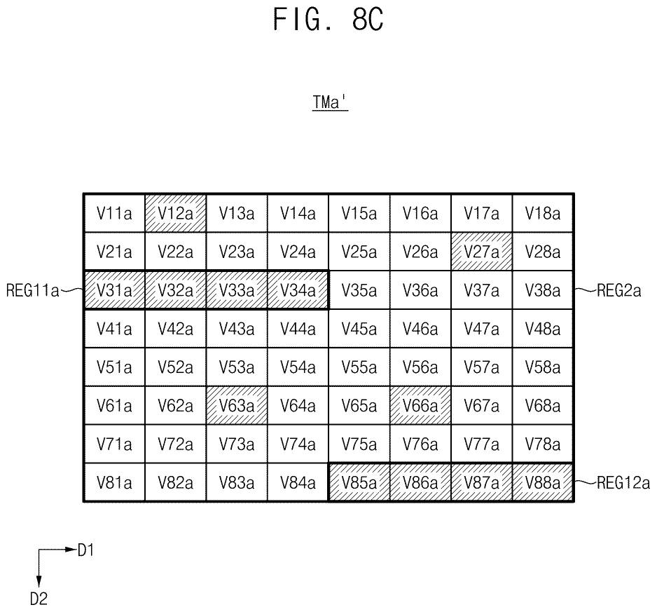

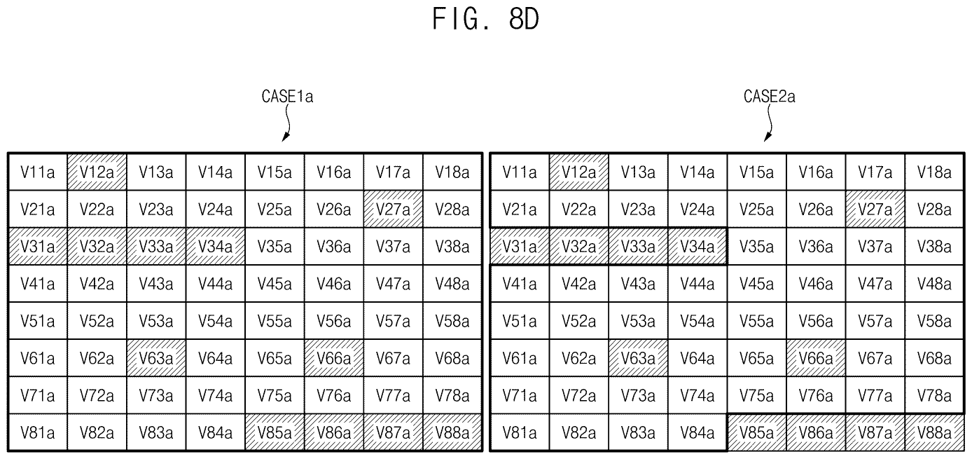

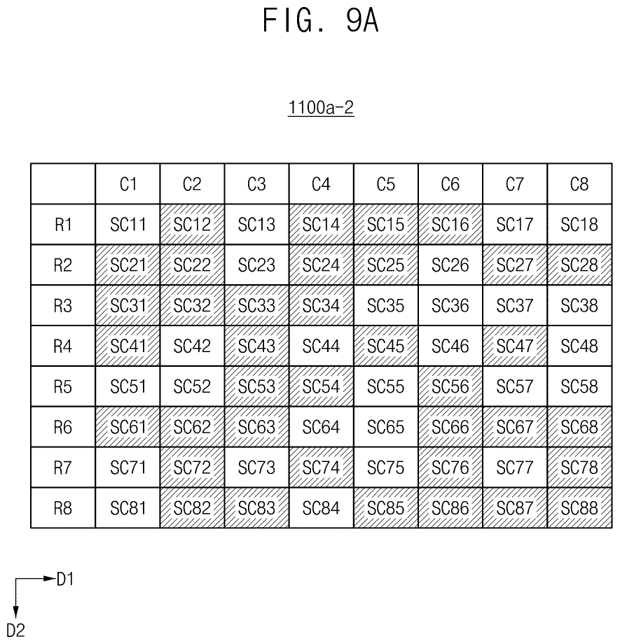

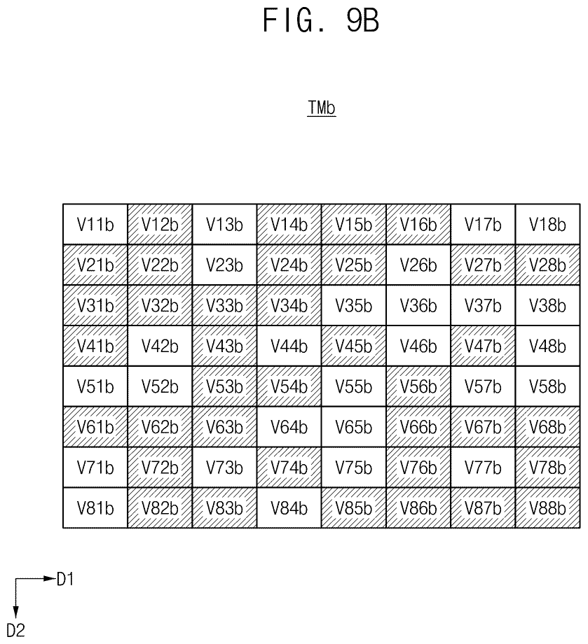

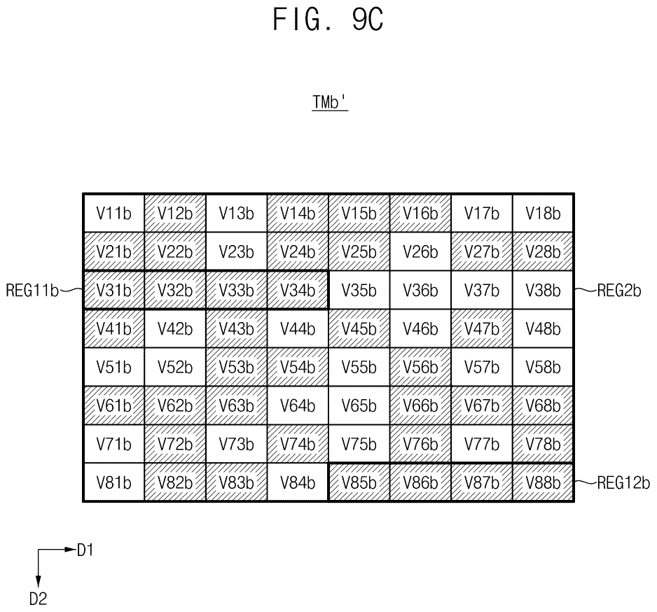

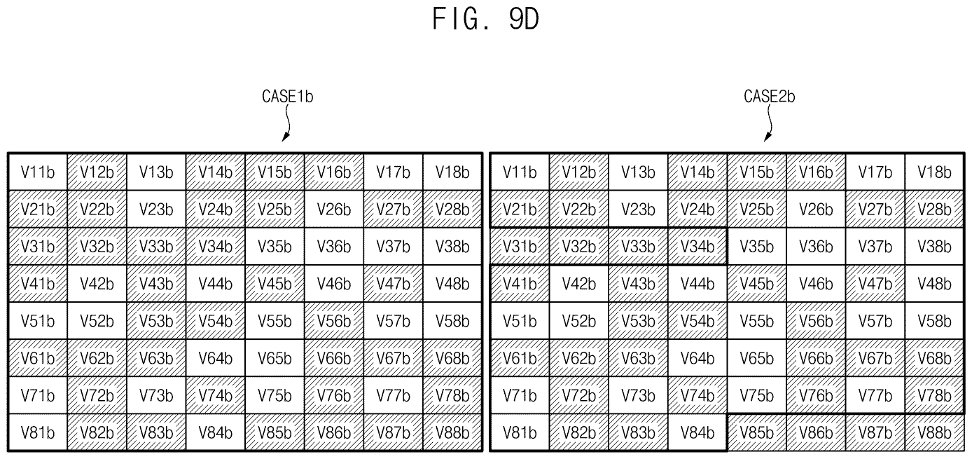

As a result of the first test operation, a test map may be generated (and thereby obtained), e.g., based on a first test result of the first test operation (operation S200). For example, the test map may include information representing whether each of the plurality of semiconductor products on the test board is normal or defective. The test map may be also called a DUT map. Examples of the test map will be described with reference to FIGS. 8A, 8B, 8C, 8D, 9A, 9B, 9C and 9D.

The test map is divided into a first region and a second region based on a channel layout data for the test board and the first test result (operation S300). The channel layout data may include information associated with or related to the configuration of the plurality of test channels formed in the test board. The first region may identify semiconductor products among the plurality of the semiconductor products that share the same test channel and have been determined to be entirely defective, and the second region may identify semiconductor products other than those identified in the first region.

A second test operation is performed to determine whether defects of semiconductor products identified by the first region are board-related defects or defects of the semiconductor products themselves, using information of the first and second regions, a first probability model, and a second probability model (operation S400). The first and second probability models may be predetermined or predefined. Unlike the first test operation, the second test operation may be an operation to determine whether the defect of each defective semiconductor product, determined as defective during the first test operation, is due to its own defect (e.g., whether it is a real defect or intrinsic defect) or due to an operational error of the test board which is not a defect of the semiconductor product itself (e.g., whether it is a fake defect).

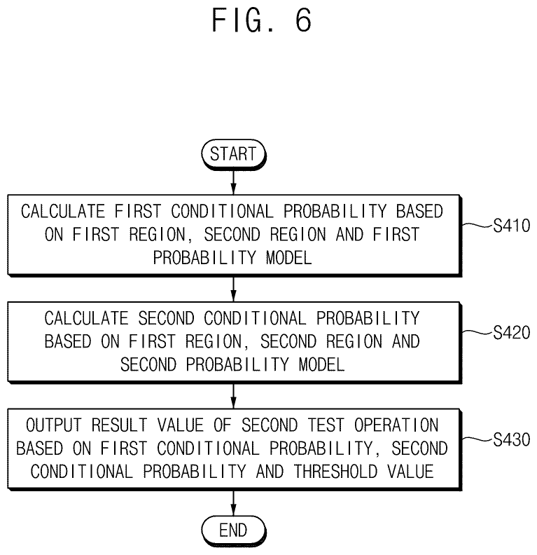

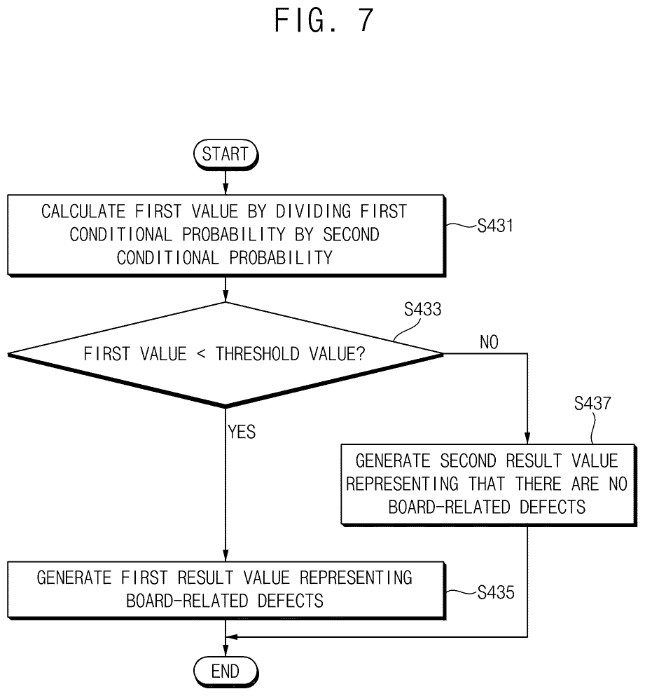

In some example embodiments, the second test operation may be performed using a probability-based model support calculation method. The probability-based model support calculation method may be a statistical approach used to evaluate how well a given model fits to observed data by leveraging probability theory. This method typically involves at least the following steps: 1) likelihood estimation; the probability of the observed data is computed under different models. This is often done using maximum likelihood estimation (MLE), where the model parameters are adjusted to maximize the likelihood of the data, 2) model comparison; competing models are assessed based on their likelihoods. A common approach is the likelihood ratio test, which compares the goodness of fit between two models by taking the ratio of their likelihoods, 3) Bayesian inference: in some cases, prior probabilities are incorporated using Bayesian methods, where the posterior probability of a model is computed based on observed data and prior knowledge, 4) support calculation; the degree to which a model is supported by the data is quantified using statistical measures such as log-likelihood, Bayes factors, or information criteria, and 5) decision making; based on the computed probabilities, a decision is made regarding which model best explains the data. If the likelihood ratio or other statistical measures indicate a significant difference, one model may be preferred over another. For example, the second test operation may be performed based on a likelihood ratio test. Operation S400 will be described with reference to FIGS. 6 and 7.

For the mass production of semiconductor products, multiple semiconductor products may be mounted on a single test board, which is then installed in test equipment to perform a test operation. The test board may include multiple test channels, and the test equipment may apply test signals to the semiconductor products through the test channels, and some semiconductor products may share a single test channel and may receive test signals through the test channel. In this case, a communication error may occur between a specific test channel and corresponding semiconductor products due to an abnormal arrangement of the semiconductor products, a poor connection, etc. on a specific test channel, resulting in determining the corresponding semiconductor products as defective even if the semiconductor products themselves are not defective. Because such semiconductor products are determined as defective due to the characteristic of the test board, the semiconductor products may be determined to be normal when they are retested under standard test conditions. A defect caused by the characteristic of the test board may be described as a board-related defect.

Conventionally, detecting and addressing board-related defects requires a significant amount of time and cost, and, in some cases, the test equipment may not be able to identify and resolve such defects independently.

In the semiconductor product testing method according to example embodiments, the test map may be generated by performing the first test operation on each of the plurality of semiconductor products using the test board with the channel-shared structure, the test map may be divided into the first region and the second region using the channel layout data of the test board and the first test result from the first test operation, and the second test operation may be performed to determine whether the defect of each semiconductor product identified as defective in the first test operation is due to the board-related defect or due to defect of the semiconductor product itself. This evaluation is performed using information from the divided first and second regions and the predefined probability models. Accordingly, compared to conventional methods that utilize graphic processing units (GPUs) or servers, the board-related defects can be detected and addressed in relatively less time and at a lower cost. In addition, the test equipment may be fully automated and may detect and address the board-related defects independently without the need for additional GPUs or servers.

FIG. 2 is a block diagram illustrating a test equipment according to example embodiments.

Referring to FIG. 2, a test equipment 1000 includes a test board 1100, a first test module 1200 and a second test module 1300.

As is traditional in the field of the disclosed technology, features and embodiments are described and illustrated in the drawings, in terms of “modules.” Those skilled in the art will appreciate that modules are physically implemented by electronic (or optical) circuits such as logic circuits, discrete components, microprocessors, hard-wired circuits, memory elements, and the like, which may be formed using semiconductor-based fabrication techniques or other manufacturing technologies. In the case of the modules being implemented by microprocessors or similar, they may be programmed using software (e.g., microcode) to perform various functions discussed herein and may optionally be driven by firmware and/or software. Alternatively, each module may be implemented with dedicated hardware, or as a combination of dedicated hardware to perform some functions and a processor (e.g., one or more programmed microprocessors and associated circuitry) to perform other functions. Also, each module of the embodiments may be physically separated into two or more interacting and discrete modules without departing from the scope of the inventive concepts. Further, the modules of the embodiments may be physically combined into more complex modules without departing from the scope of the inventive concepts. A “module” may be, but is not limited to, a software and/or hardware component, such as a field programmable gate array (FPGA) or an application specific integrated circuit (ASIC), which performs certain tasks. A “module” may be configured to reside in a tangible addressable storage medium and be configured to execute on one or more processors. For example, a “module” may include components such as software components, object-oriented software components, class components and task components, and processes, functions, routines, segments of program code, drivers, firmware, microcode, circuitry, data, databases, data structures, tables, arrays, and variables.

The test board 1100 may be designed to accommodate a plurality of semiconductor products SC. The plurality of semiconductor products SC mounted on the test board 1100 may be tested simultaneously and/or sequentially. The test board 1100 includes a plurality of channels for receiving test signals and communicating with the plurality of semiconductor products SC. As will be described with reference to FIGS. 3A, 3B, 3C and 3D, two or more semiconductor products may share a single test channel.

In some example embodiments, the test board 1100 may be attachable and detachable. For example, while performing the test operation, the test board 1100 may be attached to the test equipment 1000 to test the plurality of semiconductor products SC, and the test board 1100 may be detached from the test equipment 1000 while the tests for the plurality of semiconductor products SC are being prepared or completed. The test equipment 1000 may include a test board connector to which the test board 1100 is attached while performing the test operation and the test board 1100 is detached from the test board connector while preparing another test operation. For example, the test board 1100 may be detached from the test board connector for mounting semiconductor products to be tested.

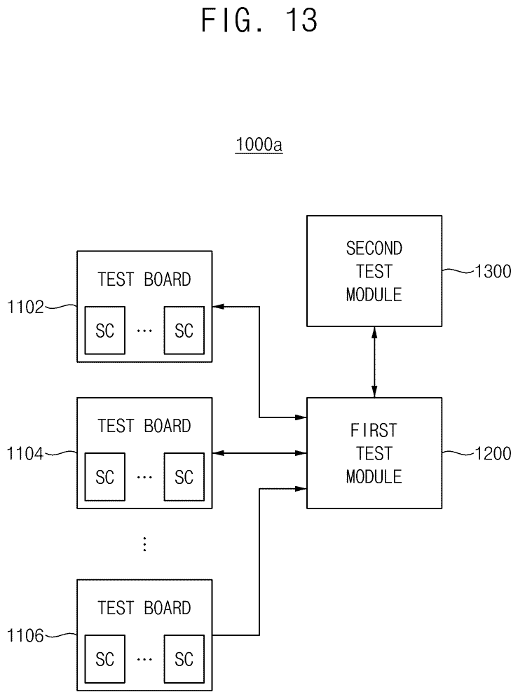

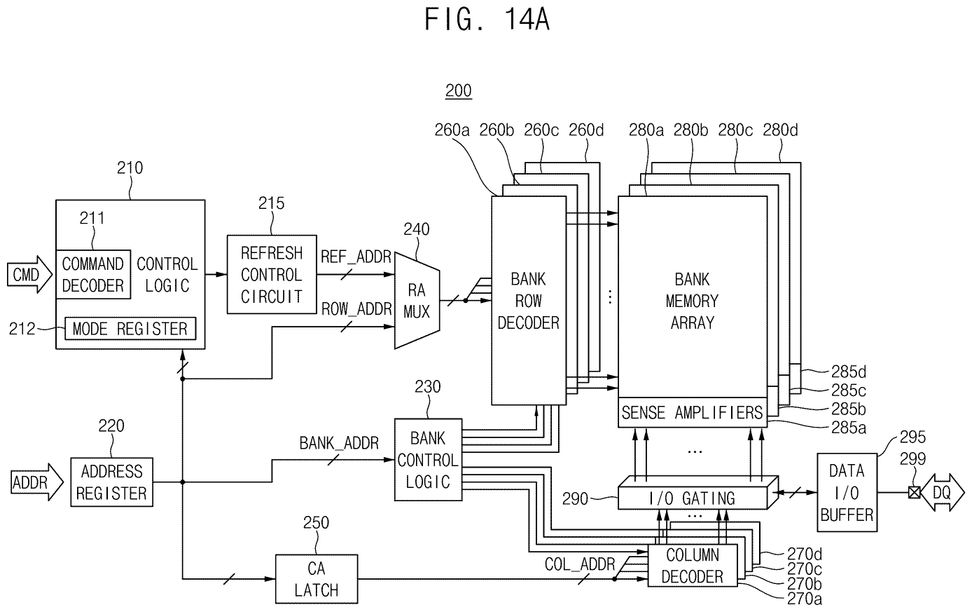

Although FIG. 2 illustrates an example where the test equipment 1000 includes one test board 1100, example embodiments are not limited thereto. For example, as will be described with reference to FIG. 13, the test equipment may include a plurality of test boards, and semiconductor products mounted on the plurality of test boards may be tested simultaneously and/or sequentially.

The first test module 1200 performs a first test operation to determine whether each of the plurality of semiconductor products SC mounted on the test board 1100 is normal or defective, and generates a test map reflecting the first test result of the first test operation.

The second test module 1300 divides the test map into a first region and a second region based on channel layout data for the test board 1100, and performs a second test operation to determine whether defects of semiconductor products within the first region are board-related defects that are caused by a characteristic of the test board 1100 or whether the defects result from defects of the semiconductor products themselves based on information of the first and second regions, a first probability model, and a second probability model. The first region may identify semiconductor products among the plurality of the semiconductor products that share the same test channel, and have been determined to be entirely defective, and the second region may identify semiconductor products other than those identified in the first region.

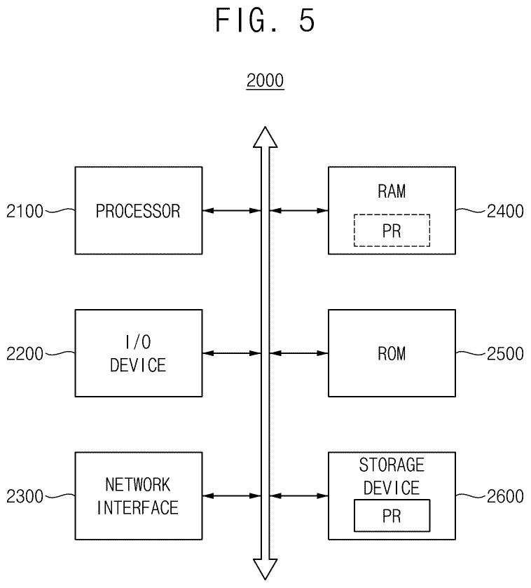

In some example embodiments, as will be described with reference to FIG. 5, the test equipment 1000 may include a processor and a storage device (or a storage medium). The first and second test modules 1200 and 1300 may perform the first and second test operations, respectively, using the processor and the storage device. Each of the first and second test modules 1200 and 1300 may include the processor and the storage device.

As described above, the test equipment 1000 that includes the test board 1100, the first test module 1200 and the second test module 1300 may perform the semiconductor product testing using the probability model-based test according to example embodiments described with reference to FIG. 1. For example, the test board 1100 and the first test module 1200 may perform operations S100 and S200 in FIG. 1, and the second test module 1300 may perform operations S300 and S400 in FIG. 1.

In some example embodiments, the first and second test modules 1200 and 1300 may be implemented as a single integrated module. In other example embodiments, the first and second test modules 1200 and 1300 may be implemented as separate and different modules.

FIGS. 3A, 3B, 3C and 3D are diagrams for describing a test board included in a test equipment of FIG. 2.

Referring to FIG. 3A, a plurality of semiconductor products SC11, SC12, SC13, SC14, SC15, SC16, SC17, SC18, SC21, SC22, SC23, SC24, SC25, SC26, SC27, SC28, SC31, SC32, SC33, SC34, SC35, SC36, SC37, SC38, SC41, SC42, SC43, SC44, SC45, SC46, SC47, SC48, SC51, SC52, SC53, SC54, SC55, SC56, SC57, SC58, SC61, SC62, SC63, SC64, SC65, SC66, SC67, SC68, SC71, SC72, SC73, SC74, SC75, SC76, SC77, SC78, SC81, SC82, SC83, SC84, SC85, SC86, SC87 and SC88 may be mounted on a test board 1100a.

The plurality of semiconductor products SC11 to SC88 may be arranged and mounted in a two-dimensional (2D) matrix formation. For example, sixty four semiconductor products SC11 to SC88 may be arranged to form eight rows R1, R2, R3, R4, R5, R6, R7 and R8 extending in a first direction D1 and eight columns C1, C2, C3, C4, C5, C6, C7 and C8 extending in a second direction D2 crossing (e.g., perpendicular to) the first direction D1. For example, the semiconductor products SC11, SC12, SC13, SC14, SC15, SC16, SC17 and SC18 may form the first row R1, and the semiconductor products SC11, SC21, SC31, SC41, SC51, SC61, SC71 and SC81 may form the first column C1. The rows R1 to R8 and the columns C1 to C8 may be conceptually illustrated to explain the arrangement of the semiconductor products SC11 to SC88, and may be arranged differently in the test board 1100a.

In some example embodiments, the test board 1100a may include a substrate and a plurality of sockets that are disposed on the substrate and used for fixing the plurality of semiconductor products SC11 to SC88 on the test board 1100a. For example, the substrate may have an upper surface and a lower surface opposite to each other. For example, the substrate may be a printed circuit board (PCB). For example, the plurality of sockets may provide mechanical and electrical connections between the substrate and the plurality of semiconductor products SC11 to SC88, and may be formed in various ways. For example, the plurality of sockets may be slots, or the like.

Referring to FIGS. 3B, 3C and 3D, examples of a plurality of test channels included in the test board 1100a of FIG. 3A are illustrated, and examples of channel layout data CLDa, CLDb and CLDc representing information associated with the configuration of the plurality of test channels are illustrated.

In some example embodiments, as illustrated in FIG. 3B, a plurality of test channels CH1a, CH2a, CH3a, CH4a, CH5a, CH6a, CH7a, CH8a, CH9a, CH10a, CH11a, CH12a, CH13a, CH14a, CH15a and CH16a may be formed to receive test signals for testing corresponding semiconductor products arranged along rows of the channel layout data in the first direction D1 (e.g., in a row direction). Some of the semiconductor products SC11 to SC88 arranged in a row among the rows can share one test channel. For example, among the semiconductor products SC11 to SC18 arranged in the first row R1, the semiconductor products SC11, SC12, SC13 and SC14 may be commonly connected to the test channel CH1a, and the semiconductor products SC15, SC16, SC17 and SC18 may be commonly connected to the test channel CH9a.

In some example embodiments, as illustrated in FIG. 3C, a plurality of test channels CH1b, CH2b, CH3b, CH4b, CH5b, CH6b, CH7b, CH8b, CH9b, CH10b, CH11b, CH12b, CH13b, CH14b, CH15b and CH16b may be formed to accommodate corresponding semiconductor products arranged along columns of the channel layout data in the second direction D2 (e.g., in a column direction). Some of the semiconductor products SC11 to SC88 arranged in the second direction D2 may share one test channel. For example, among the semiconductor products SC11 to SC81 arranged in the first column C1, the semiconductor products SC11, SC21, SC31 and SC41 may be commonly connected to the test channel CH1b, and the semiconductor products SC51, SC61, SC71 and SC81 may be commonly connected to the test channel CH9b.

In some example embodiments, as illustrated in FIG. 3D, a plurality of test channels CH1c, CH2c, CH3c and CH4c may be formed to receive test signals for testing corresponding semiconductor products as illustrated in FIG. 3D. Some of the plurality of semiconductor products SC11 to SC88 may share one test channel. For example, the semiconductor products SC11, SC12, SC13, SC14, SC15, SC16, SC17, SC18, SC21, SC22, SC23, SC24, SC31, SC32, SC33 and SC34 may be commonly connected to the test channel CH1c.

Although FIGS. 3A, 3B, 3C and 3D illustrate a specific number of semiconductor products and a specific number of test channels, example embodiments are not limited thereto.

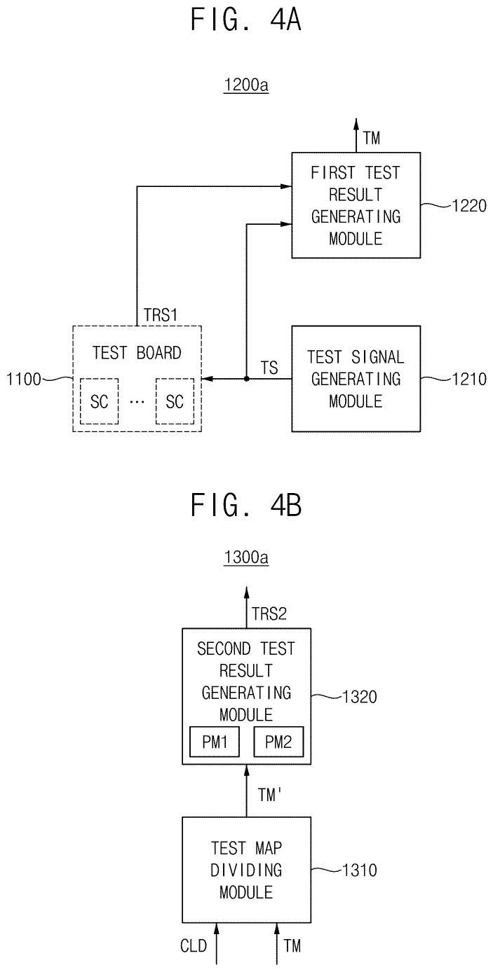

FIGS. 4A and 4B are block diagrams illustrating examples of a first test module and a second test module included in a test equipment of FIG. 2.

Referring to FIG. 4A, a first test module 1200a may include a test signal generating module 1210 and a first test result generating module 1220.

The test signal generating module 1210 may generate a test signal TS, and may provide the test signal TS to the test board 1100. For example, the plurality of semiconductor products SC may receive the test signal TS. As described above, the test board 1100 may include the plurality of test channels, some semiconductor products may share one test channel, and thus the semiconductor products sharing the same test channel may receive the test signal TS through the same test channel.

The first test result generating module 1220 may receive the test signal TS from the test signal generating module 1210, and may receive a plurality of first test result signals TRS1 from the test board 1100. For example, each of the plurality of semiconductor products SC may generate and output a respective one of the plurality of first test result signals TRS1 as a result of the first test operation performed in response to the test signal TS. The first test result generating module 1220 may perform the first test operation, in response to the test signal TS, to determine whether each of the plurality of semiconductor products SC is normal or defective based on the respective one of the plurality of first test result signals TRS1, and may generate a test map TM representing a result of the first test operation. For example, the test map TM may include information representing whether each semiconductor product is normal or defective.

In some example embodiments, the test signal generating module 1210 and the first test result generating module 1220 may be implemented as a single integrated module. In other example embodiments, the test signal generating module 1210 and the first test result generating module 1220 may be implemented as separate and different modules.

Referring to FIG. 4B, a second test module 1300a may include a test map dividing module 1310 and a second test result generating module 1320.

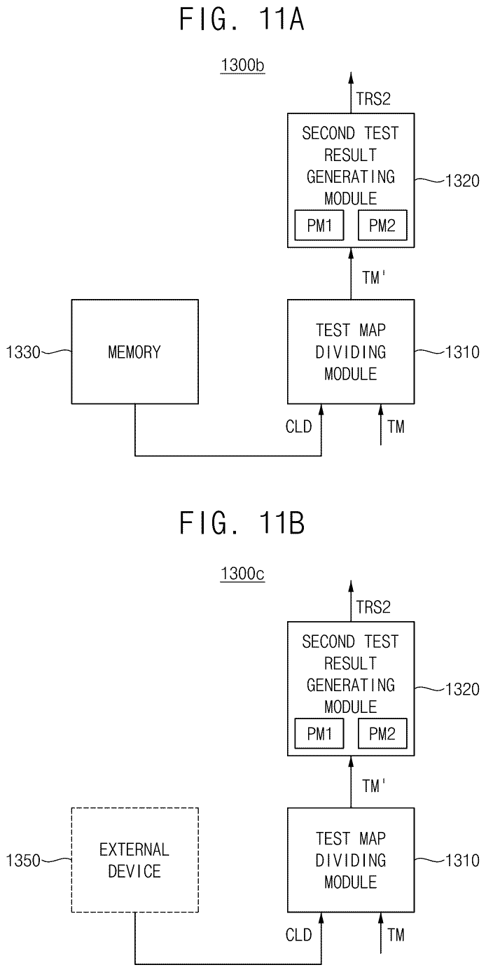

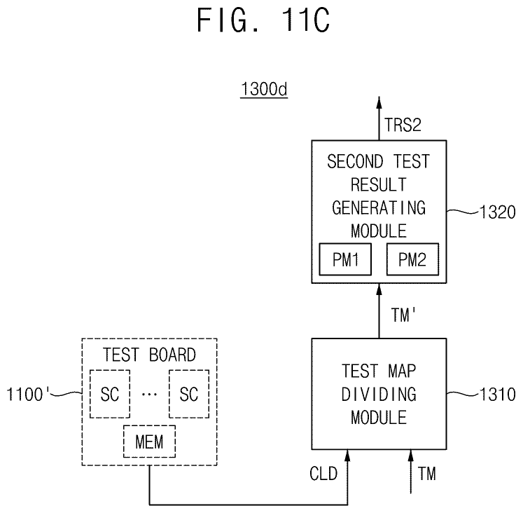

The test map dividing module 1310 may receive channel layout data CLD for the test board 1100. The channel layout data CLD may be stored in various locations according to example embodiments as will be described with reference to FIGS. 11A, 11B and 11C. The test map dividing module 1310 may divide the test map TM into a first region and a second region based on the channel layout data CLD and the first test result from the first test operation, and may generate a region-divided test map TM′. The first region may identify semiconductor products among the plurality of semiconductor products that share the same test channel and have been determined to be entirely defective, and the second region may represent semiconductor products other than those identified in the first region.

The second test result generating module 1320 may perform the second test operation to determine whether the defects of the semiconductor products identified in the first region are the board-related defects caused by the characteristic of the test board 1100 or defects of the semiconductor products themselves, using information of the first and second regions, a first probability model PM1 and a second probability model PM2 (e.g., based on the region-divided test map TM′, the first probability model PM1 and the second probability model PM2), and may generate a second test result signal TRS2 representing a result of the second test operation. For example, the first probability model PM1 and the second probability model PM2 may be stored in the second test result generating module 1320.

In some example embodiments, the test map dividing module 1310 and the second test result generating module 1320 may be implemented as a single integrated module. In other example embodiments, the test map dividing module 1310 and the second test result generating module 1320 may be implemented as separate and different modules.

FIG. 5 is a block diagram illustrating a test equipment according to example embodiments.

Referring to FIG. 5, a test equipment 2000 includes a processor 2100, an input/output (I/O) device 2200, a network interface 2300, a random access memory (RAM) 2400, a read only memory (ROM) 2500 and a storage device 2600. FIG. 5 illustrates an example where all of the first and second test modules 1200 and 1300 in FIG. 2 are implemented in software. For convenience of illustration, a component corresponding to the test board 1100 in FIG. 2 is omitted.

The test equipment 2000 may be a computing system. For example, the computing system may be either a fixed computing system such as a desktop computer, a workstation or a server, or may be a portable computing system such as a laptop computer.

The processor 2100 may be used to perform computational operations and/or calculations. For example, the processor 2100 may include a core or a processor core for executing an arbitrary instruction set (for example, intel architecture-32 (IA-32), 64 bit extension IA-32, x86-64, PowerPC, Sparc, MIPS, ARM, IA-64, etc.). For example, the processor 2100 may access a memory (e.g., the RAM 2400 or the ROM 2500) through a bus, and may execute instructions stored in the RAM 2400 or the ROM 2500. As illustrated in FIG. 5, the RAM 2400 may store a program PR corresponding to the first and second test modules 1200 and 1300 in FIG. 2 or at least some elements of the program PR, and the program PR may allow the processor 2100 to perform operations for testing the semiconductor products using the probability model-based test (e.g., operations S100, S200, S300 and S400 in FIG. 1). In some example embodiments, the processor 2100 may include a plurality of cores and/or may include a cache memory to enhance computational capabilities.

Specifically, the program PR may include a plurality of instructions and/or procedures executable by the processor 2100, and the plurality of instructions and/or procedures included in the program PR may allow the processor 2100 to perform the operations for testing the semiconductor products using the probability model-based test according to example embodiments. Each of the procedures may denote a series of instructions for performing a certain task. A procedure may be a function, a routine, a subroutine, or a subprogram. Each of the procedures may process data provided from outside the test equipment 2000 and/or data generated by another procedure.

The storage device 2600 may store data used for operations of the processor 2100 and the test equipment 2000. For example, the storage device 2600 may store the program PR. The program PR or at least some elements of the program PR may be loaded from the storage device 2600 to the RAM 2400 for being executed by the processor 2100. The storage device 2600 may store a source file written in a program language, and the processor 2100 may generate the program PR by compiling the source file, and load at least some portions of the program PR to the RAM 2400.

The storage device 2600 may store data, which is to be processed by the processor 2100, or data obtained through processing by the processor 2100. The processor 2100 may process the data stored in the storage device 2600 to generate new data, based on the program PR and may store the generated data in the storage device 2600.

In some example embodiments, the storage device 2600 may include any non-transitory computer-readable storage medium used to provide commands and/or data to a computer. For example, the non-transitory computer-readable storage medium may include a volatile memory such as a static random access memory (SRAM), a dynamic random access memory (DRAM), or the like, and a nonvolatile memory such as a flash memory, a magneto-resistive random access memory (MRAM), a phase-change random access memory (PRAM), a resistive random access memory (RRAM), a ferroelectric random access memory (FRAM), or the like. The non-transitory computer-readable storage medium may be inserted into the computer, may be integrated into the computer, or may be coupled to the computer through a communication medium such as a network and/or a wireless link.

The I/O device 2200 may include an input device, such as a keyboard, a pointing device, or the like, and may include an output device such as a display device, a printer, or the like. For example, a user may trigger, through the I/O devices 2200, execution of the program PR by the processor 2100, and may provide or check various inputs, outputs and/or data, etc.

The network interface 2300 may provide access to a network outside the test equipment 2000. For example, the network may include a plurality of computing systems and communication links, and the communication links may include wired links, optical links, wireless links, or arbitrary other type links. Various inputs may be provided to the test equipment 2000 through the network interface 2300, and various outputs may be provided to another computing system through the network interface 2300.

In some example embodiments, the first and second test modules 1200 and 1300 may be implemented as instructions or program codes that may be executed by the processor 2100. In some example embodiments, the processor 2100 may be manufactured to efficiently execute instructions or program codes included in the first and second test modules 1200 and 1300.

Although FIG. 5 illustrates an example including only one processor 2100 and one storage device 2600, e.g., an example where the first and second test modules 1200 and 1300 share the processor 2100 and the storage device 2600, example embodiments are not limited thereto. For example, the test equipment 2000 may include separate processors and separate storage devices for the first and second test modules 1200 and 1300.

FIG. 6 is a flowchart illustrating an example of performing a second test operation in FIG. 1.

Referring to FIGS. 1 and 6, when performing the second test operation (operation S400), a first conditional probability may be calculated based on the information of the first and second regions and the first probability model (operation S410), and a second conditional probability may be calculated based on the information of the first and second regions and the second probability model (operation S420).

In some example embodiments, the second test operation may be performed based on the likelihood ratio test. For example, the second test operation may be performed based on a probability comparison using a Bayes factor.

In statistics, the likelihood ratio test may be a hypothesis test used to compare the goodness of fit between two competing statistical models, typically one obtained by maximizing over the entire parameter space and another obtained after imposing some constraints, based on the ratio of their likelihoods. In the likelihood ratio test, if the more constrained model (e.g., the null hypothesis) is supported by the observed data, the likelihoods of the two models may not differ significantly beyond what can be attributed to sampling error. Thus, the likelihood ratio test may evaluate whether this ratio is significantly different from one or, equivalently, whether its natural logarithm is significantly different from zero.

In some example embodiments, the first probability model may represent a model in which defects are distributed globally and randomly without being confined to any specific region. For example, the first probability model may be obtained by simulating a case in which defective semiconductor products that are determined as defective by the first test operation among the plurality of semiconductor products are randomly distributed across entire region of the test map without consideration of the first region and the second region. For example, the first probability model may correspond to the statistical model obtained by maximizing over the entire parameter space among the two competing statistical models described above.

In some example embodiments, the second probability model may represent a model in which defects occur locally and deterministically in a specific region, e.g., a model in which an abnormal region exists and a defect deterministically occurs in the abnormal region. For example, the second probability model may be obtained by simulating a case in which defective semiconductor products that are determined as defective by the first test operation among the plurality of semiconductor products are deterministically identified in the first region and randomly identified in the second region. For example, the second probability model may correspond to the statistical model obtained after imposing some constraints among the two competing statistical models described above.

In some example embodiments, each of the first and second probability models may be defined based on various probability variables and/or probability distributions. For example, each of the first and second probability models may be defined based on a probability mass function of a multivariate hypergeometric distribution, but example embodiments are not limited thereto.

Thereafter, a second test result of the second test operation may be output based on the first conditional probability, the second conditional probability and a predetermined threshold value (operation S430). Operation S430 will be described with reference to FIG. 7.

FIG. 7 is a flowchart illustrating an example of outputting a second test result of a second test operation in FIG. 6.

Referring to FIGS. 6 and 7, the second test result of the second test operation (operation S430) may have a first value. The first value may be calculated by dividing the first conditional probability by the second conditional probability (operation S431). For example, the first value V1 may be obtained based on Equation 1.

$$\begin{matrix}V 1 = p ( Dutmap \vert PM 1 ) / p ( Dutmap \vert PM 2 ) \\ = p ( Dutmap \vert Globally Random ) / p ( Dutmap \vert \\ Prob . 1 if AFC else Random )\end{matrix} \qquad [ Equation 1 ]$$

In Equation 1, p(Dutmap|PM1) and p(Dutmap|Globally Random) denote the first conditional probability obtained in operation S410 (e.g., a probability that is obtained under the first probability model PM1 in which defects are distributed globally and randomly), and p(Dutmap|PM2) and p(Dutmap|Prob. 1 if AFC else Random) denote the second conditional probability obtained in operation S420 (e.g., a probability that is obtained under the second probability model PM2 in which defects occur deterministically in the abnormal region). In addition, the term ‘Dutmap’ denotes the test map TM, and ‘AFC’ denotes all failed channel region, e.g., the first region in which semiconductor products share the same test channel and have been determined to be entirely defective.

The first value is compared with a predetermined threshold value, and when the first value is smaller than the predetermined threshold value (operation S433: YES), the defects of the semiconductor products identified in the first region may be determined as the board-related defects (operation S435). In this example, the semiconductor products identified in the first region may be saved through retesting. For example, the semiconductor products included in the first region may be retested using a different test board.

When the first value is greater than or equal to the predetermined threshold value (operation S433: NO), the defects of the semiconductor products included in the first region may be determined as the defects of the semiconductor products themselves and not related to the characteristic of the test board. For example, it may be determined that the semiconductor products identified in the first region have defects their own regardless of the characteristic of the test board. In this example, a defect analysis may be performed on the semiconductor products identified in the first region, or the semiconductor products identified in the first region may be treated as defective and may be discarded.

In some example embodiments, each of the first value and the predetermined threshold value may be a real number greater than zero and smaller than one. As the first value approaches zero, the second probability model gains stronger support, increasing the likelihood that the defects of the semiconductor products identified in the first region are the board-related defects. On the contrary, as the first value approaches one, the first probability model gains stronger support, increasing the likelihood that the defects of the semiconductor products included in the first region are not the board-related defects. Accordingly, a predetermined real number between zero and one may be set as the predetermined threshold value.

However, example embodiments are not limited thereto. For example, the first value may be transformed into a second value using a logarithm or similar function, and the second value, rather than the first value, may be used. For example, the second value may represent either that the defects of the semiconductor products identified in the first region are the board-related defects when the first value and/or the second value is greater than the predetermined threshold value or that the defects of the semiconductor products included in the first region are not the board-related defects when the first value and/or the second value is smaller than or equal to the predetermined threshold value. In addition, example embodiments may be variously changed and/or modified into various other forms.

FIGS. 8A, 8B, 8C, 8D, 9A, 9B, 9C and 9D are diagrams for describing a method of testing a semiconductor product according to example embodiments.

Referring to FIGS. 8A, 8B, 8C and 8D, an example where the first test operation and the second test operation are performed based on the test board 1100a of FIG. 3A and the channel layout data of the test channels CH1a to CH16a in FIG. 3B is illustrated.

As illustrated in FIG. 8A, when the first test operation is performed, the semiconductor products SC12, SC27, SC31, SC32, SC33, SC34, SC63, SC66, SC85, SC86, SC87 and SC88 among the plurality of semiconductor products SC11 to SC88 included in a test board 1100a-1 may be determined as defective. In FIG. 8A and subsequent figures, semiconductor products determined as defective are illustrated with hatched lines.

As a result of the first operation, a test map TMa including a plurality of determination values V11a, V12a, V13a, V14a, V15a, V16a, V17a, V18a, V21a, V22a, V23a, V24a, V25a, V26a, V27a, V28a, V31a, V32a, V33a, V34a, V35a, V36a, V37a, V38a, V41a, V42a, V43a, V44a, V45a, V46a, V47a, V48a, V51a, V52a, V53a, V54a, V55a, V56a, V57a, V58a, V61a, V62a, V63a, V64a, V65a, V66a, V67a, V68a, V71a, V72a, V73a, V74a, V75a, V76a, V77a, V78a, V81a, V82a, V83a, V84a, V85a, V86a, V87a and V88a may be obtained as illustrated in FIG. 8B. In FIG. 8B and subsequent figures, determination values corresponding to semiconductor products determined as defective are illustrated with hatched lines.

In some example embodiments, one determination value may correspond to a testing result of one semiconductor product, and may have different values depending on whether the semiconductor product is determined to be normal or defective. For example, the determination value V11a, corresponding to a testing result of the semiconductor product SC11 which has been determined to be normal, may have a first value (e.g., ‘0’). For example, the determination value V12a, corresponding to a testing result of the semiconductor product SC12 which has been determined to be defective, may have a second value (e.g., ‘1’) different from the first value. However, example embodiments are not limited thereto.

Thereafter, as illustrated in FIG. 8C, the test map TMa may be divided into a first region, including a first subregion REG11a and a second subregion REG12a, and a second region REG2a, generating a region-divided test map TMa′. For example, the first region may include a first subregion REG11a and a second subregion REG12a. The first subregion REG11a may identify the semiconductor products SC31, SC32, SC33 and SC34 that share the test channel CH3a and have been determined to be entirely defective, and the second subregion REG12a may identify the semiconductor products SC85, SC86, SC87 and SC88 that share the test channel CH16a and have been determined to be entirely defective. The second region REG2a may identify semiconductor products other than those identified in the first and second subregions REG11a and REG12a of the first region.

Thereafter, as illustrated in FIG. 8D, the second test operation described with reference to FIGS. 6 and 7 may be performed using the first probability model PM1 and the second probability model PM2. For example, a testing result of the second test operation using the first probability model PM1 is conceptually illustrated in CASE1a on the left side of FIG. 8D, and a testing result of the second test operation using the second probability model PM2 is conceptually illustrated in CASE2a on the right side of FIG. 8D. The second operation may be performed by calculating a probability under the first probability model PM1 and the second probability model PM2 based on the test map TMa for obtaining a first value, and comparing the first value with a predetermined threshold value. Thereafter, when the first value is smaller than the predetermined threshold value, it may be determined that the test map TMa supports the second probability model PM2 (e.g., defects occur deterministically in semiconductor products identified in the first regions REG11a and REG12a and occur randomly in the second region REG2a), and thus it may be determined that the defects of the semiconductor products SC31, SC32, SC33, SC34, SC85, SC86, SC87 and SC88 are board-related defects.

Referring to FIGS. 9A, 9B, 9C and 9D, an example where the first test operation and the second test operation are performed based on the test board 1100a of FIG. 3A and the channel layout data of the test channels CH1a to CH16a in FIG. 3B is illustrated. The descriptions repeated with or overlapping with descriptions of FIGS. 8A, 8B, 8C and 8D will be omitted in the interest of brevity.

As illustrated in FIG. 9A, when the first test operation is performed, the semiconductor products SC12, SC14, SC15, SC16, SC21, SC22, SC24, SC25, SC27, SC28, SC31, SC32, SC33, SC34, SC41, SC43, SC45, SC47, SC53, SC54, SC56, SC61, SC62, SC63, SC66, SC67, SC68, SC72, SC74, SC76, SC78, SC82, SC83, SC85, SC86, SC87 and SC88 among the plurality of semiconductor products SC11 to SC88 included in a test board 1100a-2 may be determined as defective.

Therefore, as illustrated in FIG. 9B, a test map TMb including a plurality of determination values V11b, V12b, V13b, V14b, V15b, V16b, V17b, V18b, V21b, V22b, V23b, V24b, V25b, V26b, V27b, V28b, V31b, V32b, V33b, V34b, V35b, V36b, V37b, V38b, V41b, V42b, V43b, V44b, V45b, V46b, V47b, V48b, V51b, V52b, V53b, V54b, V55b, V56b, V57b, V58b, V61b, V62b, V63b, V64b, V65b, V66b, V67b, V68b, V71b, V72b, V73b, V74b, V75b, V76b, V77b, V78b, V81b, V82b, V83b, V84b, V85b, V86b, V87b and V88b may be obtained.

Thereafter, as illustrated in FIG. 9C, the test map TMb may be divided into first regions REG11b and REG12b and a second region REG2b, and a region-divided test map TMb′ may be obtained.

Thereafter, as illustrated in FIG. 9D, the second test operation described with reference to FIGS. 6 and 7 may be performed using the first probability model PM1 and the second probability model PM2. For example, a testing result of the second test operation using the first probability model PM1 is conceptually illustrated in CASE1b on the left side of FIG. 9D, and a testing result of the second test operation using the second probability model PM2 is conceptually illustrated in CASE2b on the right side of FIG. 9D. The second operation may be performed by calculating a probability under the first probability model PM1 and the second probability model PM2 based on the test map TMb for obtaining a first value, and comparing the first value with a predetermined threshold value. Thereafter, when the first value is greater than the predetermined threshold value, it may be determined that the test map TMb supports the first probability model PM1 (e.g., defects occur randomly in the entire region of the first regions REG11b and REG12b and the second region REG2b), and thus it may be determined that the defects of the semiconductor products SC31, SC32, SC33, SC34, SC85, SC86, SC87 and SC88 are not the board-related defects (e.g., it may be determined that the defects of the semiconductor products SC31, SC32, SC33, SC34, SC85, SC86, SC87 and SC88 are defects of the semiconductor products themselves).

In some cases, even if the first regions REG11a and REG12a and the second region REG2a in the test map TMa are substantially the same as the first regions REG11b and REG12b and the second region REG2b in the test map TMb, the determination regarding whether the defects of the semiconductor products SC31, SC32, SC33, SC34, SC85, SC86, SC87 and SC88 are the board-related defects may be different from each other depending on defects distributions across the test maps. For example, in the test map TMa, the number of defective semiconductor products may be relatively small, the defective semiconductor products may be concentrated only in the first regions REG11a and REG12a, and thus it may be determined that there is a high possibility that the defects of the semiconductor products SC31, SC32, SC33, SC34, SC85, SC86, SC87 and SC88 are the board-related defects. On the contrary, in the test map TMb, the number of defective semiconductor products may be relatively large, a distribution of the defective semiconductor products may not correspond to a specific spatial pattern, and thus it may be determined that there is a high possibility that the defects of the semiconductor products SC31, SC32, SC33, SC34, SC85, SC86, SC87 and SC88 are not the board-related defects.

Although example embodiments are described based on the test maps obtained using a specific number of semiconductor products and test channels having a specific structure, example embodiments are not limited thereto.

In some example embodiments, the test map may not include the first region even if operation S300 is performed, and then the process may be terminated without performing operation S400. For example, when the first region does not exist in the test map, it may be determined that the board-related defects do not exist without performing operation S400.

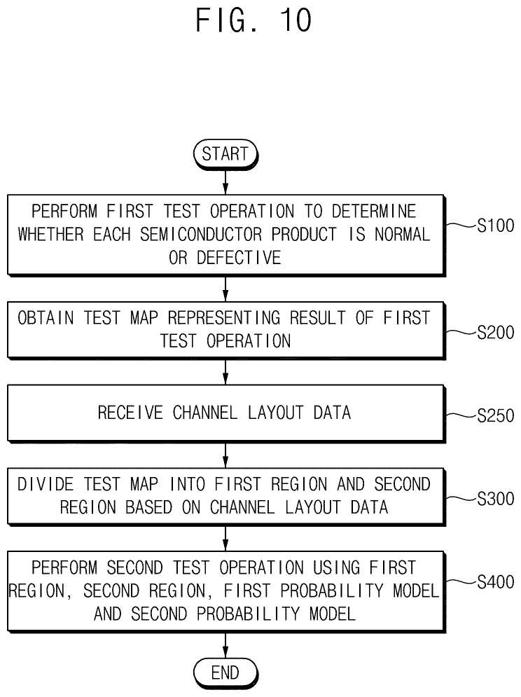

FIG. 10 is a flowchart illustrating a method of testing a semiconductor product according to example embodiments. The descriptions repeated with or overlapping with descriptions of FIG. 1 will be omitted in the interest of brevity.

Referring to FIG. 10, in a method of testing a semiconductor product according to example embodiments, operations S100, S200, S300 and S400 may be substantially the same as those described with reference to FIG. 1.

The channel layout data for the test board may be received (operation S250). For example, the channel layout data may be received internally in the test equipment. For example, the channel layout data may be received from an external device located outside the test equipment. For example, the channel layout data may be received from the test board.

FIGS. 11A, 11B and 11C are block diagrams illustrating examples of a second test module included in a test equipment of FIG. 2. The descriptions repeated with or overlapping with descriptions of FIG. 4B will be omitted in the interest of brevity.

Referring to FIG. 11A, a second test module 1300b may include a test map dividing module 1310 and a second test result generating module 1320, and may further include a memory 1330.

The second test module 1300b may be substantially the same as the second test module 1300a of FIG. 4B, except that the second test module 1300b further includes the memory 1330.

The memory 1330 may store the channel layout data CLD. The test map dividing module 1310 may operate in response to internally receiving the channel layout data CLD from the memory 1330.

Although FIG. 11A illustrates an example where the memory 1330 storing the channel layout data CLD is included in the second test module 1300b, example embodiments are not limited thereto, and the memory 1330 may be disposed at other location outside the second test module 1300b and inside the test equipment.

Referring to FIG. 11B, a second test module 1300c may include a test map dividing module 1310 and a second test result generating module 1320.

The second test module 1300c and the test map dividing module 1310 may operate in response to receiving the channel layout data CLD from an external device 1350. For example, the external device 1350 may be a device disposed outside the test equipment. For example, the channel layout data CLD may be received via wired and/or wireless communication using the I/O device 2200 and/or the network interface 2300 in FIG. 5.

Referring to FIG. 11C, a second test module 1300d may include a test map dividing module 1310 and a second test result generating module 1320.

Unlike that described with reference to FIG. 2, the test board 1100′ may further include a memory MEM that stores the channel layout data CLD. The second test module 1300d and the test map dividing module 1310 may operate in response to receiving the channel layout data CLD from the test board 1100′.

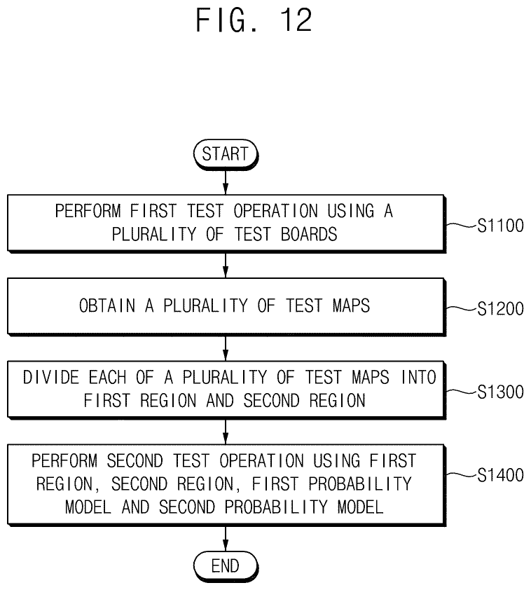

FIG. 12 is a flowchart illustrating a method of testing a semiconductor product according to example embodiments. The descriptions repeated with or overlapping with descriptions of FIG. 1 will be omitted for brevity.

Referring to FIG. 12, in a method of testing a semiconductor product according to example embodiments, a first test operation is performed to determine whether each semiconductor product is normal or defective using a plurality of test boards (operation S1100). A plurality of semiconductor products are mounted on each of the plurality of test boards. A plurality of test maps representing a result of the first test operation are generated, and thereby obtained (operation S1200). Each of the plurality of test maps is divided into a first region and a second region based on at least one channel layout data for the plurality of test boards (operation S1300). The first region may identify semiconductor products that share the same test channel and have been determined to be entirely defective, and the second region may identify semiconductor products other than those identified in the first region. A second test operation is performed to determine whether defects of semiconductor products included in the first region are board-related defects caused by a characteristic of each of the plurality of test boards, using information from the first and second regions, a first probability model and a second probability model (operation S1400). Operations S1100, S1200, S1300 and S1400 may be substantially the same as operations S100, S200, S300 and S400 in FIG. 1, respectively, except that the plurality of test boards and the plurality of test maps are used. In some example embodiments, an operation of receiving the channel layout data for each test board corresponding to operation S250 in FIG. 10 may be further performed.

In some example embodiments, the first and second test operations for the plurality of test boards may be performed sequentially. In some example embodiments, the first and second test operations for at least some of the plurality of test boards may be performed substantially simultaneously or concurrently.

FIG. 13 is a block diagram illustrating a test equipment according to example embodiments. The descriptions repeated with or overlapping with descriptions of FIG. 2 will be omitted in the interest of brevity.

Referring to FIG. 13, a test equipment 1000a includes a plurality of test boards 1102, 1104 and 1106, a first test module 1200 and a second test module 1300.

The test equipment 1000a may be substantially the same as the test equipment 1000 of FIG. 2, except that the test equipment 1000a includes the plurality of test boards 1102, 1104 and 1106. Each of the plurality of test boards 1102, 1104 and 1106 may be substantially the same as the test board 1100 in FIG. 2.

In some example embodiments, the plurality of test boards 1102, 1104 and 1106 may be attachable and detachable.

In some example embodiments, the test equipment 1000a may be equipped with one test board at a time, and the plurality of test boards 1102, 1104 and 1106 may be tested sequentially. For example, the test board 1102 may be attached to the test equipment 1000a, and the first and second test operations may be performed on semiconductor products SC included in the test board 1102. After the first and second test operations for the test board 1102 are completed, the test board 1102 may be detached from the test equipment 1000a, the test board 1104 may be attached to the test equipment 1000a, and the first and second test operations may be performed on semiconductor products SC included in the test board 1104.

In some example embodiments, the test equipment 1000a may be equipped with two or more test boards at a time, and at least some of and the plurality of test boards 1102, 1104 and 1106 may be performed substantially simultaneously. For example, the test boards 1102 and 1104 may be attached to the test equipment 1000a simultaneously, and the first and second test operations may be performed simultaneously on the semiconductor products SC included in the test boards 1102 and 1104.

In some example embodiments, all of the plurality of test boards 1102, 1104 and 1106 may have the same structure and the same type. In this example, when testing a test board that is initially attached, channel layout data corresponding to the test board may be received once, and when testing other test boards thereafter, the operation of receiving the channel layout data may be omitted.

In some example embodiments, at least some of the plurality of test boards 1102, 1104 and 1106 may have different structures and different types. In this example, channel layout data corresponding to the test board may be received whenever the structure and type of the test board being attached are changed.

As will be appreciated by those skilled in the art, example embodiments may be embodied as a system, method, computer program product, and/or a computer program product embodied in one or more computer readable medium(s) having computer readable program code embodied thereon. The computer readable program code may be provided to a processor of a general purpose computer, special purpose computer, or other programmable data processing apparatus. The computer readable medium may be a computer readable signal medium or a computer readable storage medium. The computer readable storage medium may be any tangible medium that can contain or store a program for use by or in connection with an instruction execution system, apparatus, or device. For example, the computer readable medium may be a non-transitory computer readable medium.

FIGS. 14A and 14B are block diagrams illustrating examples of a semiconductor product according to example embodiments.

Referring to FIG. 14A, an example where a semiconductor product is provided in the form of a semiconductor chip is illustrated, and an example where the semiconductor chip is a memory (or memory chip) is illustrated. For example, a memory 200 may be one of various volatile memories such as a DRAM.

The memory 200 may include a control logic 210, a refresh control circuit 215, an address register 220, a bank control logic 230, a row address multiplexer 240, a column address latch 250, a row decoder, a column decoder, a memory cell array, a sense amplifier unit, an input/output (I/O) gating circuit 290, a data I/O buffer 295 and a data I/O pad 299.

The memory cell array may include a plurality of memory cells. The memory cell array may include a plurality of bank arrays, e.g., first to fourth bank arrays 280a, 280b, 280c and 280d. The row decoder may include a plurality of bank row decoders, e.g., first to fourth bank row decoders 260a, 260b, 260c and 260d connected to the first to fourth bank arrays 280a, 280b, 280c and 280d, respectively. The column decoder may include a plurality of bank column decoders, e.g., first to fourth bank column decoders 270a, 270b, 270c and 270d connected to the first to fourth bank arrays 280a, 280b, 280c and 280d, respectively. The sense amplifier unit may include a plurality of bank sense amplifiers, e.g., first to fourth bank sense amplifiers 285a, 285b, 285c and 285d connected to the first to fourth bank arrays 280a, 280b, 280c and 280d, respectively.

The first to fourth bank arrays 280a to 280d, the first to fourth bank row decoders 260a to 260d, the first to fourth bank column decoders 270a to 270d, and the first to fourth bank sense amplifiers 285a to 285d may form first to fourth banks, respectively. For example, the first bank array 280a, the first bank row decoder 260a, the first bank column decoder 270a, and the first bank sense amplifier 285a may form the first bank, the second bank array 280b, the second bank row decoder 260b, the second bank column decoder 270b, and the second bank sense amplifier 285b may form the second bank, the third bank array 280c, the third bank row decoder 260c, the third bank column decoder 270c, and the third bank sense amplifier 285c may form the third bank, and the fourth bank array 280d, the fourth bank row decoder 260d, the fourth bank column decoder 270d, and the fourth bank sense amplifier 285d may form the fourth bank.

The address register 220 may receive an address ADDR including a bank address BANK_ADDR, a row address ROW_ADDR and a column address COL_ADDR from a controller located outside the memory 200. The address register 220 may provide the received bank address BANK_ADDR to the bank control logic 230, may provide the received row address ROW_ADDR to the row address multiplexer 240, and may provide the received column address COL_ADDR to the column address latch 250.

The bank control logic 230 may generate bank control signals in response to receipt of the bank address BANK_ADDR. One of the first to fourth bank row decoders 260a to 260d corresponding to the received bank address BANK_ADDR may be activated in response to the bank control signals generated by the bank control logic 230, and one of the first to fourth bank column decoders 270a to 270d corresponding to the received bank address BANK_ADDR may be activated in response to the bank control signals generated by the bank control logic 230.

The refresh control circuit 215 may generate a refresh address REF_ADDR in response to receipt of a refresh command or entrance of any self-refresh mode. For example, the refresh control circuit 215 may include a refresh counter that is configured to sequentially change the refresh address REF_ADDR from a first address of the memory cell array to a last address of the memory cell array. The refresh control circuit 215 may receive control signals from the control logic 210.

The row address multiplexer 240 may receive the row address ROW_ADDR from the address register 220, and may receive the refresh address REF_ADDR from the refresh control circuit 215. The row address multiplexer 240 may selectively output the row address ROW_ADDR or the refresh address REF_ADDR. A row address (e.g., the row address ROW_ADDR or the refresh address REF_ADDR) output from the row address multiplexer 240 may be applied to the first to fourth bank row decoders 260a to 260d.

The activated one of the first to fourth bank row decoders 260a to 260d may decode the row address output from the row address multiplexer 240, and may activate a wordline corresponding to the row address. For example, the activated bank row decoder may apply a wordline driving voltage to the wordline corresponding to the row address.

The column address latch 250 may receive the column address COL_ADDR from the address register 220, and may temporarily store the received column address COL_ADDR. The column address latch 250 may apply the temporarily stored or received column address COL_ADDR to the first to fourth bank column decoders 270a to 270d.

The activated one of the first to fourth bank column decoders 270a to 270d may decode the column address COL_ADDR output from the column address latch 250, and may control the I/O gating circuit 290 to output data corresponding to the column address COL_ADDR.

The I/O gating circuit 290 may include a circuitry for gating I/O data. For example, although not shown, the I/O gating circuit 290 may include an input data mask logic, read data latches for storing data output from the first to fourth bank arrays 280a to 280d, and write drivers for writing data to the first to fourth bank arrays 280a to 280d.

Data DQ to be read from one of the first to fourth bank arrays 280a to 280d may be sensed by a sense amplifier coupled to the one bank array, and may be stored in the read data latches. The data DQ stored in the read data latches may be provided to the controller via the data I/O buffer 295 and the data I/O pad 299. Data DQ received via the data I/O pad 299 that are to be written to one of the first to fourth bank arrays 280a to 280d may be provided from the controller to the data I/O buffer 295. The data DQ received via the data I/O pad 299 and provided to the data I/O buffer 295 may be written to the one bank array via the write drivers in the I/O gating circuit 290.

The control logic 210 may control an operation of the memory 200. For example, the control logic 210 may generate control signals for the memory 200 to perform a data write operation or a data read operation. The control logic 210 may include a command decoder 211 that decodes a command CMD received from the controller and a mode register 212 that sets an operation mode of the memory 200.

Referring to FIG. 14B, an example where a semiconductor product is provided in the form of a semiconductor chip is illustrated, and an example where the semiconductor chip is a memory (or memory chip) is illustrated. For example, a memory 300 may be one of various nonvolatile memories such as a NAND flash memory.

The memory 300 may include a memory cell array 310, an address decoder 320, a page buffer circuit 330, a data input/output (I/O) circuit 340, a voltage generator 350 and a control circuit 360.

The memory cell array 310 may be connected to the address decoder 320 via a plurality of string selection lines SSL, a plurality of wordlines WL and a plurality of ground selection lines GSL. The memory cell array 310 may be further connected to the page buffer circuit 330 via a plurality of bitlines BL. The memory cell array 310 may include a plurality of memory cells (e.g., a plurality of nonvolatile memory cells) that are connected to the plurality of wordlines WL and the plurality of bitlines BL. The memory cell array 310 may be divided into a plurality of memory blocks BLK1, BLK2, . . . , BLKz each of which includes memory cells.

In some example embodiments, the plurality of memory cells may be arranged in a two-dimensional (2D) array structure or a three-dimensional (3D) vertical array structure. A three-dimensional vertical array structure may include vertical cell strings that are vertically oriented such that at least one memory cell is located over another memory cell. The at least one memory cell may comprise a charge trap layer. The following patent documents, which are hereby incorporated by reference in their entirety, describe suitable configurations for a memory cell array including a 3D vertical array structure, in which the three-dimensional memory array is configured as a plurality of levels, with wordlines and/or bitlines shared between levels: U.S. Pat. Nos. 7,679,133; 8,553,466; 8,654,587; 8,559,235; and US Pat. Pub. No. 2011/0233648.

The control circuit 360 may receive a command CMD and an address ADDR from a controller located outside the memory 300, and may control erasure, programming and read operations of the memory 300 based on the command CMD and the address ADDR. An erasure operation may include performing a sequence of erase loops, and a programming operation may include performing a sequence of program loops. Each program loop may include a program operation and a program verification operation. Each erase loop may include an erase operation and an erase verification operation. The read operation may include a normal read operation and data recovery read operation.

For example, the control circuit 360 may generate control signals CON, which are used for controlling the voltage generator 350, and may generate control signal PBC for controlling the page buffer circuit 330, based on the command CMD, and may generate a row address R_ADDR and a column address C_ADDR based on the address ADDR. The control circuit 360 may provide the row address R_ADDR to the address decoder 320 and may provide the column address C_ADDR to the data I/O circuit 340.

The address decoder 320 may be connected to the memory cell array 310 via the plurality of string selection lines SSL, the plurality of wordlines WL and the plurality of ground selection lines GSL. For example, in the data erase/write/read operations, the address decoder 320 may determine at least one of the plurality of wordlines WL as a selected wordline, at least one of the plurality of string selection lines SSL as a selected string selection line, and at least one of the plurality of ground selection lines GSL as a selected ground selection line, based on the row address R_ADDR.

The voltage generator 350 may generate voltages VS that are used for an operation of the memory 300 based on a power PWR and the control signals CON. The voltages VS may be applied to the plurality of string selection lines SSL, the plurality of wordlines WL and the plurality of ground selection lines GSL via the address decoder 320. In addition, the voltage generator 350 may generate an erase voltage VERS that is used for the erase operation based on the power PWR and the control signals CON.

The page buffer circuit 330 may be connected to the memory cell array 310 via the plurality of bitlines BL. The page buffer circuit 330 may include a plurality of page buffers. The page buffer circuit 330 may store data DAT to be programmed into the memory cell array 310 or may read data DAT sensed from the memory cell array 310. In other words, the page buffer circuit 330 may operate as a write driver or a sensing amplifier according to an operation mode of the memory 300.

The data I/O circuit 340 may be connected to the page buffer circuit 330 via data lines DL. The data I/O circuit 340 may provide the data DAT from the outside of the memory 300 to the memory cell array 310 via the page buffer circuit 330 or may provide the data DAT from the memory cell array 310 to the outside of the memory 300, based on the column address C_ADDR.

Although the semiconductor product according to example embodiments is described based on a DRAM and a NAND flash memory, the semiconductor product according to example embodiments may be or include any volatile memory, and/or any nonvolatile memory, e.g., a static random access memory (SRAM), a phase-change random access memory (PRAM), a resistive random access memory (RRAM), a magneto-resistive random access memory (MRAM), a ferroelectric random access memory (FRAM), etc.

FIGS. 15A and 15B are diagrams illustrating examples of a semiconductor product according to example embodiments.

Referring to FIGS. 15A and 15B, examples where a semiconductor product is provided in the form of a semiconductor package including semiconductor chips are illustrated.

For example, as illustrated in FIG. 15A, a semiconductor package 700 may include a base substrate 710, and a plurality of semiconductor chips CHP1, CHP2 and CHP3 stacked on the base substrate 710. For example, each of the semiconductor chips CHP1 to CHP3 may be a memory chip, and the semiconductor package 700 may be a memory package.

In some example embodiments, the semiconductor chips CHP1 to CHP3 may be stacked on the base substrate 710 such that a surface on which I/O pads are formed faces upwards. In some example embodiments, with respect to each of the semiconductor chips CHP1 to CHP3, the I/O pads may be arranged near one side of the semiconductor substrate. As such, the semiconductor chips CHP1 to CHP3 may be stacked in a scalariform, or in a stepped shape, such that the I/O pads of each semiconductor chip may be exposed. In such stacked state, the semiconductor chips CHP1 to CHP3 may be electrically connected to the base substrate 710 through bonding wires BW.

The stacked semiconductor chips CHP1 to CHP3 and the plurality of bonding wires BW may be fixed by a sealing member 740, and adhesive members 730 may intervene between the base substrate 710 and the semiconductor chips CHP1 to CHP3. Conductive bumps 720 may be formed on a bottom surface of the base substrate 710 for electrical connections to an external device.

For example, as illustrated in FIG. 15B, a semiconductor package 800 may include a base substrate 810, and a plurality of semiconductor chips CHP1, CHP2 and CHP3 stacked on the base substrate 810. The descriptions repeated with or overlapping with descriptions of FIG. 15A will be omitted for brevity.

Each of the semiconductor chips CHP1 to CHP3 may further include through silicon vias (TSVs) 830. Conductive bumps 820 and a sealing member 850 may be substantially the same as the conductive bumps 720 and the sealing member 740 in FIG. 15A, respectively.

In some example embodiments, with respect to each of the semiconductor chips CHP1 to CHP3, the TSVs 830 may be arranged at the same locations in each semiconductor chip. As such, the semiconductor chips CHP1 to CHP3 may be stacked such that the TSVs 830 of each semiconductor chip may be completely overlapped (e.g., arrangements of the TSVs 830 may be perfectly matched in the semiconductor chips CHP1 to CHP3). In such stacked state, the semiconductor chips CHP1 to CHP3 may be electrically connected to one another and the base substrate 810 through the TSVs 830 and conductive material 840.

Although example embodiments are described as the semiconductor product is provided in the form of the semiconductor chip and/or the semiconductor package, example embodiments are not limited thereto. For example, the semiconductor product may be provided in the form of solution products, e.g., a solid state drive (SSD), a universal flash storage (UFS), a multimedia card (MMC), an embedded MMC (eMMC), a secure digital (SD) card, a micro SD card, a memory stick, a chip card, a universal serial bus (USB) card, a smart card, a compact flash (CF) card, etc.

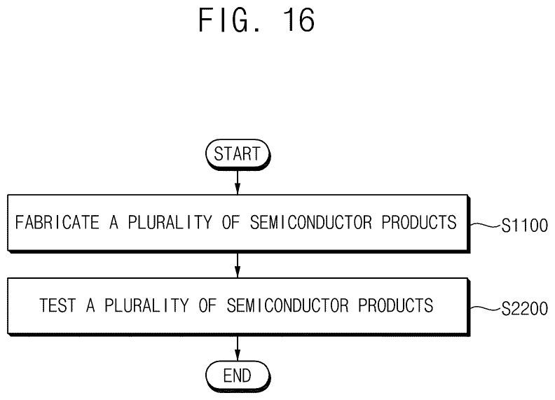

FIG. 16 is a flowchart illustrating a method of manufacturing a semiconductor product according to example embodiments.

Referring to FIG. 16, in a method of manufacturing a semiconductor product according to example embodiments, a plurality of semiconductor products are fabricated (operation S2100). For example, a plurality of wafers, each of which includes multiple semiconductor products, may be fabricated by semiconductor processes such as an oxidation process, a photolithography process, an etching process, a deposition process, an ion implantation process, a metal wiring process, etc. Thereafter, the plurality of semiconductor products may be fabricated or manufactured by an assembly process, a packaging process, etc.

The plurality of semiconductor products are tested (operation S2200). For example, operation S2200 may be performed based on the method of testing the semiconductor product using the probability model-based test according to example embodiments described with reference to FIGS. 1 through 13. For example, the test map may be obtained by performing the first test operation on each of the plurality of semiconductor products using the test board having the channel-shared structure, the test map may be divided into the first region and the second region using the channel layout data for the test board, and the second test operation may be performed to determine whether each defective semiconductor product determined as defective by the first test operation has the board-related defect using the divided regions and the predefined probability models.

The example embodiments may be applied to various electronic devices and systems that include the semiconductor products. For example, the example embodiments may be applied to systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IOT) device, an internet of everything (IoE) device, an e-book reader, a virtual reality (VR) device, an augmented reality (AR) device, a robotic device, a drone, an automotive, etc.

The foregoing is illustrative of example embodiments and is not to be construed as limiting thereof. Although some example embodiments have been described, those skilled in the art will readily appreciate that many modifications are possible in the example embodiments without materially departing from the novel teachings and advantages of the example embodiments. Accordingly, all such modifications are intended to be included within the scope of the example embodiments as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of testing a semiconductor product, the method comprising:
performing a first test operation on a plurality of semiconductor products mounted on a test board to determine whether each of the plurality of semiconductor products is normal or defective, the test board including a plurality of test channels configured to receive test signals, and two or more semiconductor products sharing a single test channel among the plurality of test channels;
generating a test map based on a first result of the first test operation;
dividing the test map into a first region and a second region based on channel layout data for the test board, the first region identifying semiconductor products, among the plurality of the semiconductor products, that share the same test channel and have been determined to be entirely defective, and the second region identifying semiconductor products other than those identified in the first region; and
performing a second test operation to determine whether defects of semiconductor products identified in the first region are board-related defects caused by a characteristic of the test board, using information of the first and second regions, a first probability model, and a second probability model.

2. The method of claim 1, wherein the second test operation is performed based on a likelihood ratio test.

3. The method of claim 2, wherein the first probability model is obtained by simulating a case in which defective semiconductor products that have been determined as defective during the first test operation are randomly distributed across the test map including the first region and the second region, and the second probability model is obtained by simulating a case in which defective semiconductor products that have been determined as defective by the first test operation are deterministically distributed in the first region and randomly distributed in the second region.

4. The method of claim 3, wherein performing the second test operation includes:
calculating a first conditional probability based on information of the first and second regions and the first probability model;
calculating a second conditional probability based on information of the first region and second regions and the second probability model; and
outputting a second test result of the second test operation using the first conditional probability, the second conditional probability, and a predetermined threshold value.

5. The method of claim 4, wherein outputting the second test result of the second test operation includes:
calculating a first value by dividing the first conditional probability by the second conditional probability; and
comparing the first value with the predetermined threshold value, and determining, when the first value is smaller than the predetermined threshold value, that the defects of the semiconductor products identified in the first region are board-related defects, and determining, when the first value is greater than or equal to the predetermined threshold value, that the defects of the semiconductor products identified in the first region are not board-related defects.

6. The method of claim 5, wherein, upon determining that the defects of the semiconductor products identified in the first region are board-related defects, the semiconductor products identified in the first region are re-tested using a different test board.

7. The method of claim 5, wherein, each of the first value and the predetermined threshold value is a real number greater than zero and smaller than one.

8. The method of claim 7, wherein, as the first value approaches zero, a likelihood that the defects of the semiconductor products identified in the first region are the board-related defects is increased, and as the first value approaches one, a likelihood that the defects of the semiconductor products included in the first region are not the board-related defects is increased.

9. The method of claim 1, wherein the first test operation and the second test operation are performed by test equipment on which the test board is mounted.

10. The method of claim 9, wherein the first test operation and the second test operation are performed using the channel layout data stored in the test equipment.

11. The method of claim 9, wherein the first test operation and the second test operation are performed using the channel layout data from an external device located outside the test equipment.

12. The method of claim 9, wherein the first test operation and the second test operation are performed using the channel layout data stored in the test board.

13. Test equipment comprising:
a test board including a plurality of test channels for testing a plurality of semiconductor products mounted on the test board, each of the plurality of test channels configured to receive test signals, and two or more semiconductor products sharing one test channel among the plurality of test channels;
a first test module configured to perform a first test operation to determine whether each of the plurality of semiconductor products is normal or defective, and to generate a test map representing a result of the first test operation; and
a second test module configured to divide the test map into a first region and a second region based on channel layout data for the test board, and to perform a second test operation to determine whether defects of semiconductor products included in the first region are board-related defects caused by a characteristic of the test board, using information of the first and second regions, a first probability model, and a second probability model, the first region identifying semiconductor products that share the same test channel and have been determined to be entirely defective, the second region identifying semiconductor products other than those identified in the first region.

14. The test equipment of claim 13, wherein the second test module includes:
at least one processor; and
a non-transitory computer readable medium configured to store program codes executable by the at least one processor,
wherein the at least one processor is configured, by executing the program codes, to:
divide the test map into the first region and the second region; and
perform the second test operation.

15. The test equipment of claim 13, further comprising a memory configured to store the channel layout data, wherein the second test module is configured to receive the channel layout data from the memory and to perform the second test operation based on the channel layout data.

16. The test equipment of claim 13, wherein the second test module is configured to receive the channel layout data from an external device located outside the test equipment and to perform the second test operation based on the channel layout data.

17. The test equipment of claim 13, wherein the test board further includes a memory configured to store the channel layout data, and the second test module is configured to receive the channel layout data from the test board and to perform the second test operation based on the channel layout data.

18. The test equipment of claim 13, further including a test board connector configured to mount and remove the test board.

19. A method of manufacturing a semiconductor product, the method comprising:
fabricating a plurality of semiconductor products; and
testing, using a test equipment, the plurality of semiconductor products mounted on a test board including a plurality of test channels for receiving test signals, wherein two or more semiconductor products share one test channel among the plurality of test channels,
wherein testing the plurality of semiconductor products includes:
performing a first test operation to determine whether each of the plurality of semiconductor products mounted on the test board is normal or defective;
generating a test map representing a result of the first test operation;
dividing the test map into a first region and a second region based on channel layout data for the test board, the first region identifying semiconductor products that share the same test channel and have been determined to be entirely defective, the second region identifying semiconductor products other than those identified in the first region; and
performing a second test operation to determine whether defects of semiconductor products identified in the first region are board-related defects caused by a characteristic of the test board, using information of the first and second regions, a first probability model and a second probability model.

20. The method of claim 19, wherein, after the first and second test operations for the plurality of semiconductor products on the test board are completed, the test board is detached from the test equipment, a second test board on which a plurality of second semiconductor products are mounted is attached to the test equipment, and the first and second test operations for the plurality of second semiconductor products are performed.
